(19) United States
(12) Patent Application Publication
(10) Pub. No.: US 2025/0223969 A1
(43) Pub. Date: Jul. 10, 2025

(54) MEMBRANE FAN

(71) Applicant: TAIWAN MICROLOOPS CORP., New Taipei City (TW)

(72) Inventors: Chun-Hung LIN, New Taipei City (TW); Chun-Teng CHIU, New Taipei City (TW)

(21) Appl. No.: 18/587,328

(22) Filed: Feb. 26, 2024

(30) Foreign Application Priority Data
Jan. 9, 2024 (TW) 113100901

(51) Int. Cl. F04D 25/06; F04D 29/38; H10N 30/50; H10N 30/87

(52) U.S. Cl. CPC F04D 25/06; F04D 29/388; H10N 30/50; H10N 30/875

(57) ABSTRACT

A membrane fan includes a supporter, a blowing glass blade and an actuator. The blowing glass blade has a fixed end connected to the supporter and a free end extended toward a far from the fixed end. The actuator is disposed on the blowing glass blade. Thereby, it is resistant to high temperatures and wear, has high hardness, does not cause deformation, and can extend its service life.

### BACKGROUND

### Technical Field

The disclosure relates to a fan, particularly to a membrane fan.

### Related Art

In the field of microelectronics, as electronic devices increasingly tend to be designed in ultra-thin designs and semiconductor components are highly integrated, heat dissipation treatment of heat generated within electronic devices has become an important issue. Related-art fans that use motors to drive blades to rotate do not meet the development requirements for silence and environmental protection of fan products due to poor wind orientation, low wind speed and easy diffusion, as well as high noise and severe electromagnetic interference.

Although the industry has proposed a piezoelectric ceramic fan to solve the above problems, most of the fan blades are made of metal or plastic. Metal blades are prone to undesirable situations after long-term use, such as elastic fatigue and high-temperature deformation. In addition, plastic blades are prone to various failure conditions such as hardening, cracking, and deformation under a high-temperature condition.

Therefore, how to overcome the above problems of deformation, wear and durability of metal blades or plastic blades is a technical issue to be solved by the applicant.

### SUMMARY

An object of the disclosure is to provide a membrane fan, which is resistant to high temperatures and wear, has high hardness, does not cause deformation, and can extend its service life.

To accomplish the above object, the disclosure provides a membrane fan, which includes a supporter, a blowing glass blade and an actuator. The blowing glass blade has a fixed end connected to the supporter and a free end extended toward a far from the fixed end. The actuator is disposed on the blowing glass blade.

To accomplish the above object, the disclosure provides another membrane fan, which includes a supporter, a blowing glass blade and an actuator. The blowing glass blade has a fixed end connected to the supporter and a free end extended toward a far from the fixed end. The actuator includes a magnetic inductive member is disposed on the blowing glass blade.

The disclosure further has the following functions such as simplified and manufacturing. Its output wind is concentrated and not diffused and has great orientation and high speed. In addition, no magnetic leakage will occur.

### BRIEF DESCRIPTION OF THE DRAWINGS

FIG. 1 is an exploded view of the blowing glass blade and each piezoelectric ceramic sheet of the first embodiment of the membrane fan of the disclosure;

FIG. 2 is an assembled perspective view of the first embodiment of the membrane fan of the disclosure;

FIG. 3 is an assembled cross-sectional view of the first embodiment of the membrane fan of the disclosure;

FIG. 4 is a cross-sectional view of a using status of the first embodiment of the membrane fan of the disclosure;

FIG. 5 is an assembled perspective view of the second embodiment of the membrane fan of the disclosure;

FIG. 6 is an assembled cross-sectional view of the second embodiment of the membrane fan of the disclosure;

FIG. 7 is a cross-sectional view of a using status of the second embodiment of the membrane fan of the disclosure;

FIG. 8 is a top view of the third embodiment of the membrane fan of the disclosure;

FIG. 9 is an assembled cross-sectional view of the fourth embodiment of the membrane fan of the disclosure; and

FIG. 10 is a cross-sectional view of a using status of the fourth embodiment of the membrane fan of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

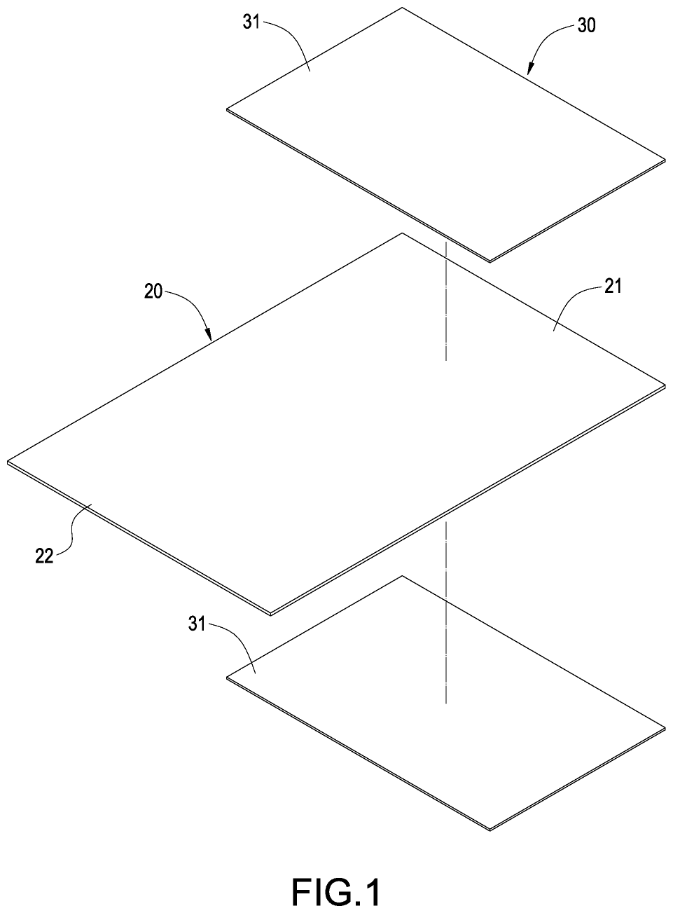

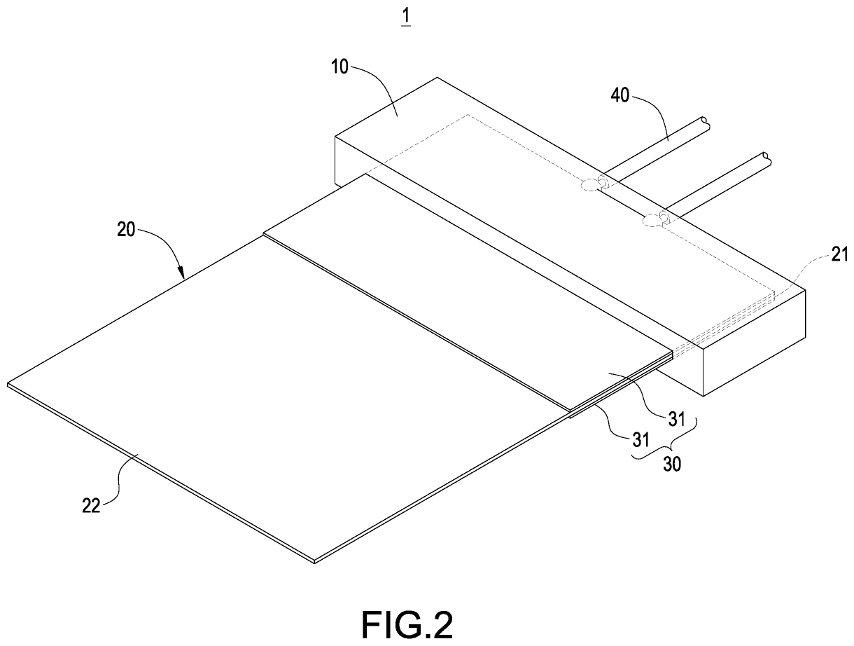

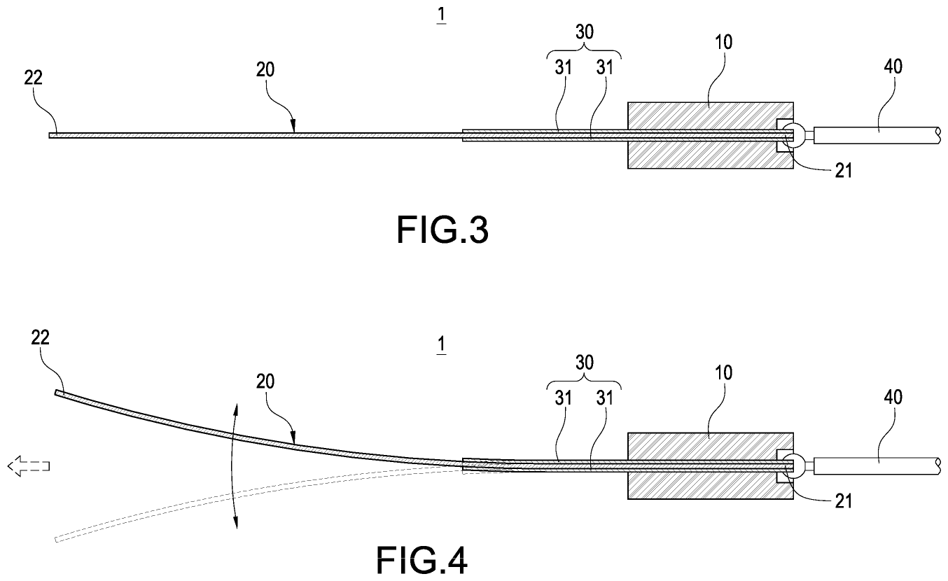

Please refer to FIGS. 1-3. The disclosure provides a membrane fan 1, which includes a supporter 10, a blowing glass blade 20 and an actuator 30.

The supporter 10 may be a printed circuit board. The blowing glass blade 20 is a thin sheet made of glass material which has a fixed end 21 connected to the supporter 10 and a free end 22 extended toward a far from the fixed end 21. The actuator 30 is disposed on the blowing glass blade 20.

In an embodiment, the membrane fan further includes a conductive wire 40 electrically connected to the actuator 30. The actuator 30 according to the embodiment includes two piezoelectric ceramic sheets 31. Each piezoelectric sheet 31 is electrically connected to the conductive wire 40. One of the piezoelectric ceramic sheets 31 is disposed on an upper side of the blowing glass blade 20, and the other piezoelectric ceramic sheet 31 is disposed on a lower side of the blowing glass blade 20, and the piezoelectric ceramic sheets 31 are disposed corresponding to each other. On a device with relatively low requirement of heat dissipation, single piezoelectric ceramic sheet 31 may be disposed. The conductive wire 40 may directly connected to each piezoelectric ceramic sheet 31 for electric connection, alternatively, the supporter 10 may be disposed as a printed circuit board type for electrically connecting the conductive wire 40 with the piezoelectric ceramic sheets 31 respectively.

According to an operation status as shown in FIG. 4, the conductive wire 40 is electrified, after each piezoelectric ceramic sheet 31 is input with voltage, the electric dipole moment will be elongated when the electric field is applied, and each piezoelectric ceramic sheet 31 will elongate along a direction of the electric field in order to resist the aforementioned change. This process of mechanical deformation caused by the action of the electric field is called “inverse piezoelectric effect.” (In fact, the inverse piezoelectric effect is a process of converting electrical energy into mechanical energy.) Thus, the blowing glass blade 20 can be driven by each piezoelectric ceramic sheet 31 to sway up and down so as to output airflow by the blowing glass blade 20.

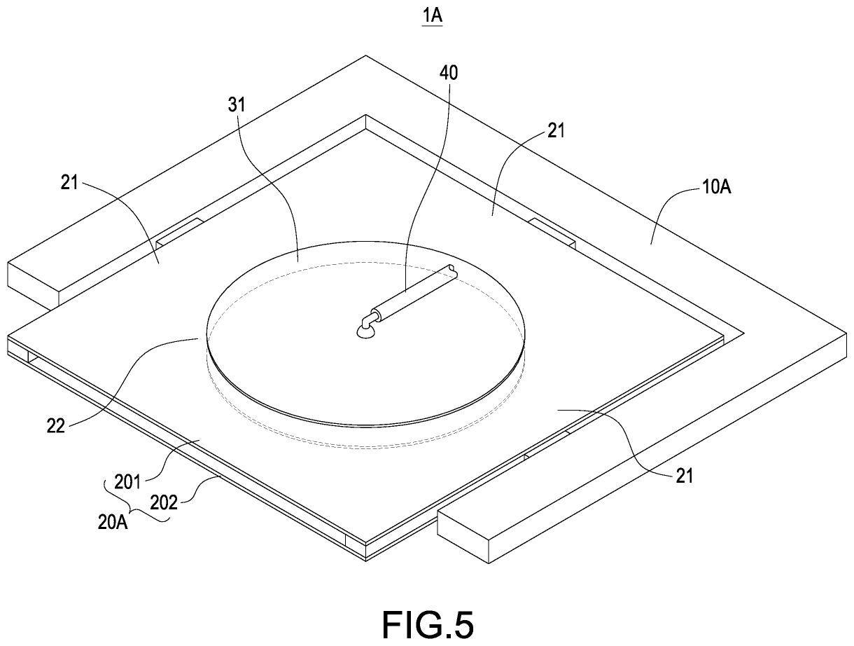

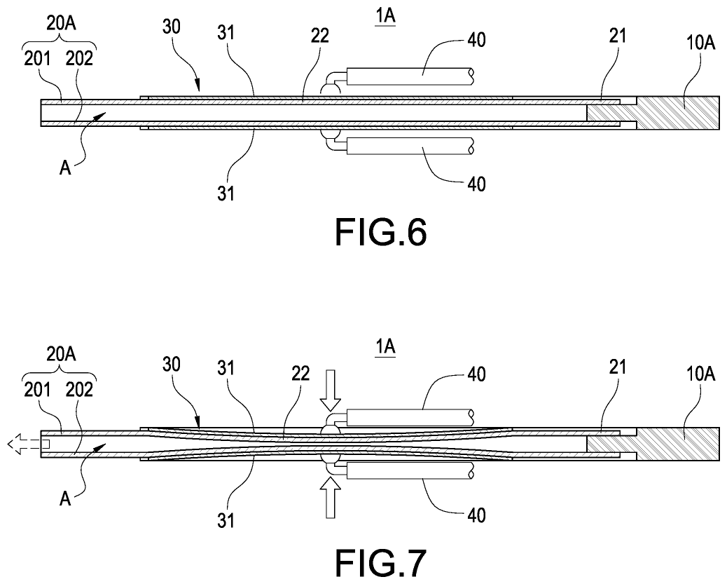

Please refer to FIGS. 5 and 6. In addition to the above embodiment, the membrane fan 1A of this embodiment differs from the above membrane fan 1 by the supporter 10A of the membrane fan 1A being of a U-shape and the blowing glass blade 20A being of a substantially rectangular shape. The blowing glass blade 20A has three fixed ends 21 and a free end 22. Each fixed end 21 is separately formed at each marginal area of the blowing glass blade 20A. The free end 22 is formed at a middle area of the blowing glass blade 20A. The blowing glass blade 20A includes an upper blowing glass blade 201 and a lower blowing glass blade 202 arranged correspondingly to the upper blowing glass blade 201. A chamber A is formed between the upper blowing glass blade 201 and lower blowing glass blade 202. Each piezoelectric ceramic sheet 31 is a circular body, the ceramic sheets 31 are disposed on external surfaces of the upper blowing glass blades 201 and the lower blowing glass blade 202 respectively so as to electrically connected with each other by the conductive wires 40 respectively.

According to an operation status as shown in FIG. 7, each conductive wire 40 is electrified, when each piezoelectric ceramic sheet 31 is input with voltage, the piezoelectric ceramic sheets 31 respectively drives the upper blowing glass blade 201 and the lower blowing glass blade 202 to sway up and down by way of the aforementioned piezoelectric effect. Outside air is sucked into the chamber A, and then the airflow will be rapidly ejected from front sides of the upper blowing glass blade 201 and the lower blowing glass blade 202.

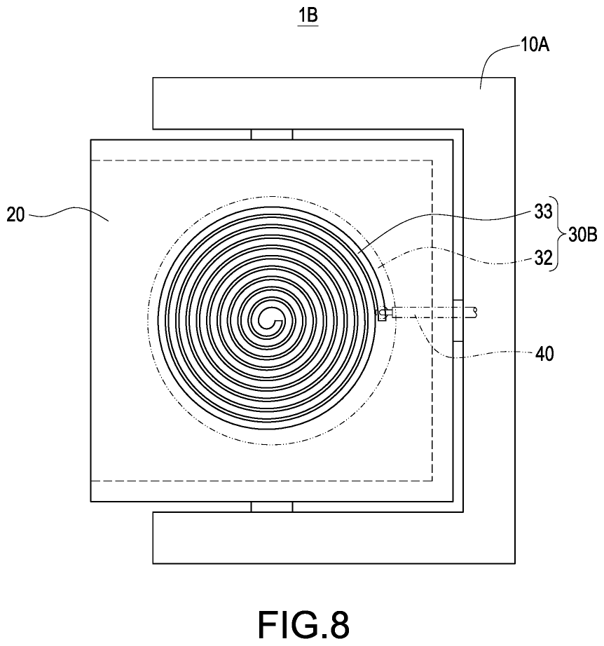

Please refer to FIG. 8. The membrane fan 1B of this embodiment differs from the above membrane fan 1A by the actuator 30B of the membrane fan 1B of the embodiment including an electromagnet 32 and a magnetic inductive member. In the embodiment, the magnetic inductive member is a conductive coil 33 disposed on the free end 22 of the blowing glass blade 20. The electromagnet 32 is connected to a conductive wire 40 and arranged correspondingly to the conductive coil 33. The conductive coil 33 may be coated on the blowing glass blade 20.

The electromagnet 32 is electrified in an operation, the blowing glass blade 20 are driven to sway up and down to output airflow via the electric current magnetic effect of the electromagnet 32 and the conductive coil 33.

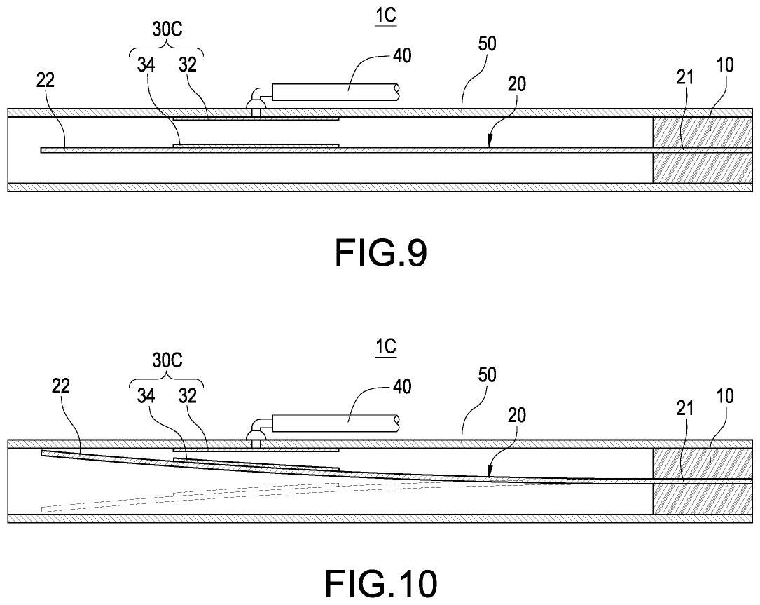

Please refer to FIGS. 9 and 10. The membrane fan 1C of the embodiment further includes a plate 50. The plate 50 has one end connected to the supporter 10, and the plate 50 has another end extended along a direction which is parallel to the blowing glass blade 20. The actuator 30C includes an electromagnet 32 and a magnetic inductive member. The magnetic inductive member of the embodiment is a permanent magnetic 34 disposed on the blowing glass blade 20 and arranged to be adjacent to the free end 22. The electromagnet 32 is connected to a conductive wire 40 and disposed on the plate 50. The electromagnet 32 is arranged correspondingly to the permanent magnet 34.

The electromagnet 32 is electrified in an operation, the blowing glass blade 20 is driven to output airflow by up and down swaying caused by the electric current magnetic effect of the electromagnet 32 and the permanent magnet 34.

While this disclosure has been described by means of specific embodiments, numerous modifications and variations could be made thereto by those skilled in the art without departing from the scope and spirit of this disclosure set forth in the claims.

What is claimed is:

1. A membrane fan comprising:
a supporter;
a blowing glass blade, comprising a fixed end connected to the supporter and a free end extended toward a far from the fixed end; and
an actuator disposed on the blowing glass blade.

2. The membrane fan of claim 1, further comprising a conductive wire electrically connected to the actuator.

3. The membrane fan of claim 2, wherein the actuator comprises two piezoelectric ceramic sheets, and each piezoelectric ceramic sheet is electrically connected to the conductive wire.

4. The membrane fan of claim 3, wherein one of the piezoelectric ceramic sheets is disposed on an upper side of the blowing glass blade, and another piezoelectric ceramic sheet is disposed on a lower side of the blowing glass blade.

5. The membrane fan of claim 3, wherein the blowing glass blade comprises an upper blowing glass blade and a lower blowing glass blade arranged correspondingly to the upper blowing glass blade, a chamber is defined between the upper blowing glass blade and lower blowing glass blade, one of the piezoelectric ceramic sheets is disposed on an external surface of the upper blowing glass blade, and another piezoelectric ceramic sheet is disposed on an external surface of the lower blowing glass blade.

6. A membrane fan comprising:
a supporter;
a blowing glass blade, comprising a fixed end connected to the supporter and a free end extended toward a far from the fixed end; and
an actuator, comprising a magnetic inductive member disposed on the blowing glass blade.

7. The membrane fan of claim 6, further comprising a conductive wire, wherein the actuator further comprises an electromagnet arranged correspondingly to the magnetic inductive member and electrically connected to the conductive wire.

8. The membrane fan of claim 7, wherein the magnetic inductive member is a conductive coil.

9. The membrane fan of claim 7, wherein the magnetic inductive member is a permanent magnet.

10. The membrane fan of claim 7, further comprising a plate, wherein an end of the plate is connected to the supporter, and another end of the plate is extended along a direction which is parallel to the blowing glass blade, and the electromagnet is disposed on the plate.
